(19) United States
(12) Patent Application Publication
(10) Pub. No.: US 2022/0093821 A1
(43) Pub. Date: Mar. 24, 2022

(54) OPTOELECTRONIC SEMICONDUCTOR DEVICE HAVING A REFLECTIVE LATTICE STRUCTURE

(71) Applicant: OSRAM Opto Semiconductors GmbH, Regensburg (DE)

(72) Inventor: Jens EBBECKE, Rohr in Niederbayern OT Helchenbach (DE)

(21) Appl. No.: 17/421,735

(22) PCT Filed: Dec. 19, 2019
(86) PCT No.: PCT/EP2019/086449

§ 371 Date: Jul. 9, 2021

(30) Foreign Application Priority Data
Jan. 10, 2019 (DE) 10 2019 100 548.5

(51) Int. Cl. H01L 33/04; H01L 33/10

(52) U.S. Cl. CPC H01L 33/04; H01L 33/10

(57) ABSTRACT

An optoelectronic semiconductor element may emit electromagnetic radiation. The optoelectronic semiconductor element may include a semiconductor body and a reflective lattice structure directly adjacent to a first main surface of the semiconductor body. The reflective lattice structure may be made of layer portions periodically arranged in the horizontal direction. The first main surface may be different from an exit surface of the electromagnetic radiation.

### CROSS-REFERENCE TO RELATED APPLICATIONS

The present application is a national stage entry according to 35 U.S.C. § 371 of PCT Application No. PCT/EP2019/086449 filed on Dec. 19, 2019; which claims priority to German Patent Application Serial No. 10 2019 100 548.5 filed on Jan. 10, 2019; all of which are incorporated herein by reference in their entirety and for all purposes.

### TECHNICAL FIELD

An optoelectronic semiconductor device having a reflective lattice is specified.

### BACKGROUND

A light emitting diode (LED) is a light emitting device based on semiconductor materials. An LED usually comprises differently doped semiconductor layers and an active zone. When electrons and holes recombine with one another in the regions of the pn junction, due, for example, to a corresponding voltage being applied, electromagnetic radiation is generated.

In general, concepts are being sought my means of which the efficiency of light emitting diodes may be increased.

### SUMMARY

An optoelectronic semiconductor device is suitable for emitting electromagnetic radiation. The optoelectronic semiconductor device comprises a semiconductor body and a reflective lattice structure which is directly adjacent to a first main surface of the semiconductor body. The reflective lattice structure comprises layer portions that are periodically arranged in a horizontal direction. The first main surface is different from an exit surface of the electromagnetic radiation.

For example, the lattice structure is implemented by a conductive layer in direct contact with the first main surface of the semiconductor body. The conductive layer is patterned periodically in the horizontal direction.

According to embodiments, the conductive layer comprises a first sub-layer of a first conductive material and a second sub-layer of a second conductive material. The first conductive material has a refractive index different from the refractive index of the second conductive material.

For example, the first conductive material is formed to be patterned periodically, and the second conductive material is arranged in spaces between portions of the first conductive material. The second conductive material may, in particular, be filled into the spaces between the patterned regions of the first conductive material. For example, the second conductive material has a smaller refractive index than the first.

A difference of the refractive indices of the first conductive material and the second conductive material may, for example, be greater than 1.0. The first conductive material may be a transparent metal oxide. The second conductive material may be silver.

According to further embodiments, the first main surface of the semiconductor body may be patterned periodically. The conductive layer is arranged between patterned semiconductor portions of the semiconductor body.

For example, the semiconductor body may comprise a first semiconductor layer of a first conductivity type, a second semiconductor layer of a second conductivity type and an active zone. The active zone may be arranged between the first semiconductor layer and the second semiconductor layer, and the first semiconductor layer, the active zone and the second semiconductor layer form a layer stack.

For example, a first main surface of the first semiconductor layer is the first main surface of the semiconductor body. The first semiconductor layer may be p-type.

According to embodiments, the lattice structure extends in the horizontal direction in a linear manner. According to further embodiments, the lattice structure may extend in the horizontal direction in a circular and concentric manner. According to further embodiments, the lattice structure may extend in the horizontal direction in a rectangular and concentric manner.

### BRIEF DESCRIPTION OF THE DRAWINGS

The accompanying drawings serve to provide an understanding of non-limiting embodiments. The drawings illustrate non-limiting embodiments and, together with the description, serve for explanation thereof. Further non-limiting embodiments and many of the intended advantages will become apparent directly from the following detailed description. The elements and structures shown in the drawings are not necessarily shown to scale relative to each other. Like reference numerals refer to like or corresponding elements and structures.

FIG. 1A shows a schematic cross-sectional view of an optoelectronic semiconductor device according to embodiments.

FIG. 1B shows a schematic cross-sectional view of an optoelectronic semiconductor device according to further embodiments.

FIGS. 2A to 2C each show examples of views of a first main surface of the optoelectronic semiconductor device according to embodiments.

### DETAILED DESCRIPTION

In the following detailed description, reference is made to the accompanying drawings, which form a part of the disclosure and in which specific exemplary embodiments are shown for purposes of illustration. In this context, directional terminology such as “top”, “bottom”, “front”, “back”, “over”, “on”, “in front”, “behind”, “leading”, “trailing”, etc. refers to the orientation of the figures just described. As the components of the exemplary embodiments may be positioned in different orientations, the directional terminology is used by way of explanation only and is in no way intended to be limiting.

The description of the exemplary embodiments is not limiting, since there are also other exemplary embodiments, and structural or logical changes may be made without departing from the scope as defined by the patent claims. In particular, elements of the exemplary embodiments described below may be combined with elements from others of the exemplary embodiments described, unless the context indicates otherwise.

The terms “wafer” or “semiconductor substrate” used in the following description may include any semiconductor-based structure that has a semiconductor surface. Wafer and structure are to be understood to include doped and undoped semiconductors, epitaxial semiconductor layers, supported by a base, if applicable, and further semiconductor structures. For example, a layer of a first semiconductor material may be grown on a growth substrate made of a second semiconductor material or of an insulating material, for example sapphire. Further examples of materials for growth substrates include glass, silicon dioxide, quartz or a ceramic.

Depending on the intended use, the semiconductor may be based on a direct or an indirect semiconductor material. Examples of semiconductor materials particularly suitable for generating electromagnetic radiation include, without limitation, nitride semiconductor compounds, by means of which, for example, ultraviolet, blue or longer-wave light may be generated, such as GaN, InGaN, AlN, AlGaN, AlGaInN, AlGaInBN, phosphide semiconductor compounds by means of which, for example, green or longer-wave light may be generated, such as GaAsP, AlGaInP, GaP, AlGaP, and other semiconductor materials such as GaAs, AlGaAs, InGaAs, AlInGaAs, SiC, ZnSe, ZnO, Ga₂O₃, diamond, hexagonal BN and combinations of the materials mentioned. The stoichiometric ratio of the ternary compounds may vary. Other examples of semiconductor materials may include silicon, silicon germanium, and germanium. In the context of the present description, the term “semiconductor” also includes organic semiconductor materials.

The term “substrate” generally includes insulating, conductive or semiconductor substrates.

The terms “lateral” and “horizontal”, as used in the present description, are intended to describe an orientation or alignment which extends essentially parallel to a first surface of a semiconductor substrate or semiconductor body. This may be the surface of a wafer or a chip (die), for example.

The horizontal direction may, for example, be in a plane perpendicular to a direction of growth when layers are grown.

The term “vertical”, as used in this description, is intended to describe an orientation which is essentially perpendicular to the first surface of a substrate or semiconductor body. The vertical direction may correspond, for example, to a direction of growth when layers are grown.

To the extent used herein, the terms “have”, “include”, “comprise”, and the like are open-ended terms that indicate the presence of said elements or features, but do not exclude the presence of further elements or features. The indefinite articles and the definite articles include both the plural and the singular, unless the context clearly indicates otherwise.

In the context of this description, the term “electrically connected” means a low-ohmic electrical connection between the connected elements. The electrically connected elements need not necessarily be directly connected to one another. Further elements may be arranged between electrically connected elements.

The term “electrically connected” also encompasses tunnel contacts between the connected elements.

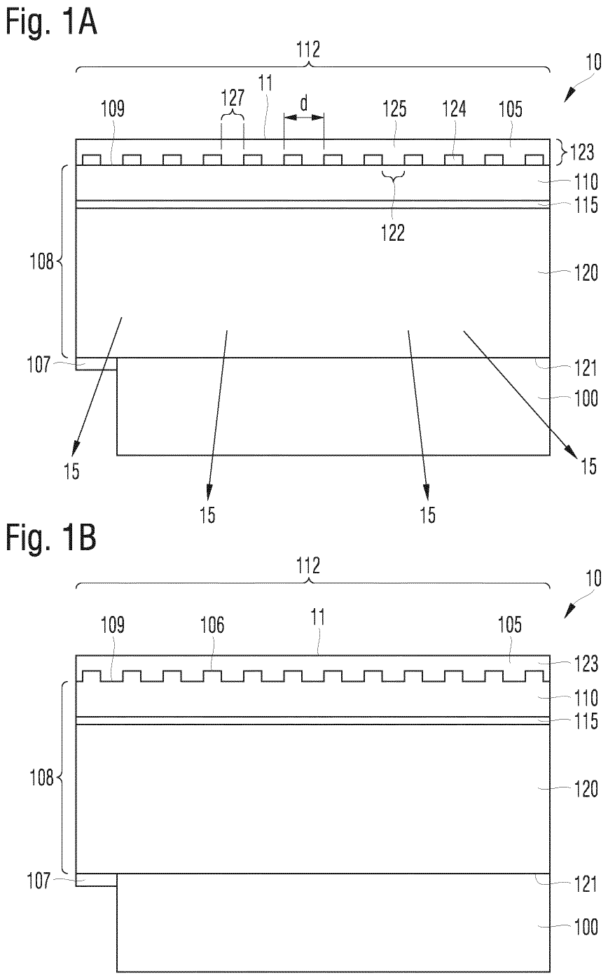

FIG. 1A shows a schematic cross-sectional view of an optoelectronic semiconductor device according to embodiments. The optoelectronic semiconductor device 10 comprises a semiconductor body 108. The optoelectronic semiconductor device 10 further comprises a reflective lattice structure 112 directly adjacent to a first main surface 109 of the semiconductor body 108. The reflective lattice structure 122 comprises layer portions which are periodically arranged in the horizontal direction. The first main surface 109 of the semiconductor body 108 is different from an exit surface 121 of the electromagnetic radiation 15.

As shown in FIG. 1A, emitted electromagnetic radiation 15 may be emitted via a bottom side of the optoelectronic semiconductor device 10 and also via side surfaces. One of the exit surfaces of the electromagnetic radiation is the second main surface 121 of the semiconductor body 108, for example. Correspondingly, the first main surface 109 is different from an exit surface of the electromagnetic radiation.

According to embodiments, the optoelectronic semiconductor device further comprises a conductive layer 123 in direct contact with the semiconductor body 108. The conductive layer 123 may be reflective or absorbent. For example, the conductive layer 123 is patterned periodically in the horizontal direction. According to embodiments, a plurality of portions 122 of the conductive layer 123 is arranged in accordance with an arrangement pattern that extends, for example, perpendicular to the first main surface 109 of the semiconductor body 108. The portions 122 of the conductive layer 123 are arranged in accordance with a constant lattice period. That is, a lateral extension of each of the portions 122 may be identical. Furthermore, a distance between adjacent portions 122 may be identical in each case. The optoelectronic semiconductor device may represent a light emitting diode (LED), for example. In particular, the electromagnetic radiation may be emitted by spontaneous emission.

For example, a period d, i.e. a grid width of the periodic structure may correspond to the range of an order of magnitude of half a wavelength of the emitted electromagnetic radiation in the corresponding medium. The term “order of magnitude” denotes the following relationship: 0.1λ/2n≤d≤10·λ/2n. Here, for example, d indicates the sum of the distance and the lateral width of the portions 122 of the conductive layer 123.

For example, according to all of the embodiments, the period of the reflective lattice structure may be less than 500 nm. According to further embodiments, the period of the reflective lattice structure may be smaller than 250 nm or smaller than 100 nm.

For example, according to all of the embodiments, the periodic structure may comprise more than 100 individual structures.

The reflective lattice structure may, for example, represent a lateral DBR mirror (“distributed Bragg reflector”). For example, the DBR mirror may be formed by a horizontally arranged sequence of portions, each having different refractive indices. For example, the layers may alternately have a high refractive index (n>1.7) and a low refractive index (n<1.7) and may be designed as a Bragg reflector.

By dimensioning the period of the lattice of the conductive layer 123 as indicated above, it is possible to provide the optoelectronic semiconductor device with a particularly clearly pronounced resonator mode. As a result, for example, the non-radiative recombination may be reduced.

In general, spontaneous emission may be regarded as emission that is stimulated by quantum-mechanical vacuum fluctuations. Due to Heisenberg's uncertainty relation, magnetic and electric fields may not be determined with any definite precision at one location. This leads to fluctuations in the electromagnetic field (also in a vacuum). In a free space, this fluctuation may have any direction and energy. Therefore it takes a few nanoseconds until an optical mode generated in this way having the excited electron and the hole state in the resonance device and the emission of a photon in this mode is randomly stimulated. This is also known as spontaneous emission. However, if there is an optical resonator in the room, the vacuum fluctuations predominantly produce optical modes that are resonant with the resonator. That is why the spontaneous lifespan in lasers is significantly reduced.

By making a particularly clearly pronounced resonator mode available, the radiative lifespan in the LED is significantly reduced. As a result, the internal quantum efficiency and therefore the overall efficiency of the optoelectronic semiconductor device increases. This enhancement of spontaneous emission is also called the Purcell effect. There is a very pronounced formation of an optical mode in resonance with the reflective lattice structure, and the radiation rate is significantly increased by the vacuum fluctuations. Furthermore, the presence of the reflective lattice structure may significantly change the emission characteristics of the LED. For example, spontaneous emission may predominantly run parallel to the optical resonator, that is to say in a horizontal direction.

For example, the semiconductor body 108 may include a first semiconductor layer 110 of a first conductivity type, for example p-type. The semiconductor body may further comprise a second semiconductor layer 120 of a second conductivity type, for example n-type. An active zone 115 may be arranged between the first and second semiconductor layers 110, 120. According to one embodiment, a layer thickness of the first semiconductor layer 110 may be dimensioned such that an optical mode is formed in a simple manner between the first main surface of the semiconductor body and the active zone. For example, the optical mode in the vertical direction may be resonant with the optical resonator. For example, the layer thickness of the first semiconductor layer may correspond to an integral multiple of half the wavelength in the first semiconductor layer. In this case, the radiative recombination rate may additionally be increased due to the Purcell's effect so that the efficiency of the optoelectronic semiconductor device increases further.

The active zone may, for example, comprise a pn junction, a double heterostructure, a single quantum well structure (SQW, single quantum well) or a multiple quantum well structure (MQW, multi quantum well) for generating radiation. The term “quantum well structure” does not imply any particular meaning here with regard to the dimensionality of the quantization. Therefore it includes, among other things, quantum wells, quantum wires and quantum dots as well as any combination of these structures.

The first semiconductor layer 110, the active zone 115 and the second semiconductor layer 120 form a semiconductor layer stack, for example. For example, a first main surface of the first semiconductor layer 110 is the first main surface 109 of the semiconductor body 108. According to embodiments, the semiconductor body 108 may be patterned to form a mesa. For example, an angle of the mesa side surfaces may be set such that a desired emission characteristic of the optoelectronic semiconductor device results. For example, the first and the second semiconductor layers 110, 120 may be based on the (In)GaN material system.

According to embodiments shown in FIG. 1A, the conductive layer 123 comprises a first sub-layer 124 of a first conductive material and a second sub-layer 125 of a second conductive material. The first conductive material may have a refractive index different form the refractive index of the second conductive material. In particular, a refractive index of the material of the first conductive sub-layer 124 may be greater than the refractive index of the material of the second conductive sub-layer 125. For example, the first conductive material may be formed to be periodically patterned over a planar first main surface 109 of the semiconductor body 108. For example, the first conductive material may be a transparent metal oxide, for example ITO (indium tin oxide). A layer thickness of the first conductive sub-layer 124 may be, for example, 50 to 150 nm. For example, a layer thickness of the first conductive sub-layer 124 may be approximately half the layer thickness of the second conductive sub-layer 125. The second conductive sub-layer 125 may have high reflectivity.

For example, the material of the second conductive sub-layer 125 may be silver or another highly reflective material. Due to the presence of the first conductive sub-layer 124, the electrical contact to the second conductive sub-layer 125 may be improved.

For example, the first conductive sub-layer 124 may be patterned at a period of λ/2n, wherein n is the refractive index of the material of the first conductive sub-layer 124. At an emission wavelength of GaN LEDs of approximately 450 nm, the first order period of this structure may be on the order of 100 nm, for example. The first conductive sub-layer 124 may be patterned, for example, using a lithography process such as electron beam lithography, nanoimprint process or laser interference exposure. According to further embodiments, lattices of a higher order may also be processed. That is to say the period corresponds to an integral multiple of half the wavelength in the corresponding medium. As a result, the spontaneous emission rate of the LED may be significantly increased, thereby increasing the efficiency as a whole.

The second conductive sub-layer 125 is formed such that it fills spaces 127 between adjacent portions of the first conductive sub-layer 124. The conductive layer 123 also constitutes a first contact element 105 for electrically contacting the first semiconductor layer 110. A second contact element 107 for contacting the second conductive semiconductor layer 120 may be arranged, for example, adjacent to a second main surface 121 of the semiconductor body 108. The optoelectronic semiconductor device may be operated by applying a forward voltage between the first and the second contact elements 105, 107. The semiconductor body 108 may be formed over a transparent substrate 100, for example. Examples of a material of the substrate 100 include sapphire, for example. Of course, other materials may also be used.

FIG. 1B shows a schematic cross-sectional view of an optoelectronic semiconductor device according to further embodiments. The optoelectronic semiconductor device 10 shown in FIG. 1B is configured in a manner similar to the device shown in FIG. 1A. In contrast to the latter, however, a first main surface 109 of the semiconductor body 108 is patterned periodically. More precisely, a plurality of protruding semiconductor portions 106 is formed in a periodic arrangement. The conductive layer 123 is formed in such a way that it fills spaces between adjacent protruding portions 106.

According to FIG. 1B, a lattice constant of the periodic pattern of the patterned first main surface 109 of the semiconductor body 108 may be selected in a manner similar to that described with reference to FIG. 1A.

For example, the conductive layer 123 according to FIG. 1B may be a silver layer. A layer thickness of the silver layer may be approximately 300 nm. In this manner, a periodic change of the refractive index is achieved, as a result of which a lateral optical mode may be generated.

According to embodiments, the lateral periodic structure may be implemented in general by forming thin layers of different refractive indices in a laterally adjacent manner. According to the embodiments described herein, these layers may be, for example, sections of conductive sub-layers, the conductive sub-layers forming the conductive layer 123 or the first contact element 105. According to further embodiments, the layers may be sections of semiconductor material 110 and a conductive layer 123. Further modifications may be made. For example, an insulating material may be patterned in a laterally periodical manner over the first semiconductor layer 110, and the spaces between the insulating material are filled with conductive material.

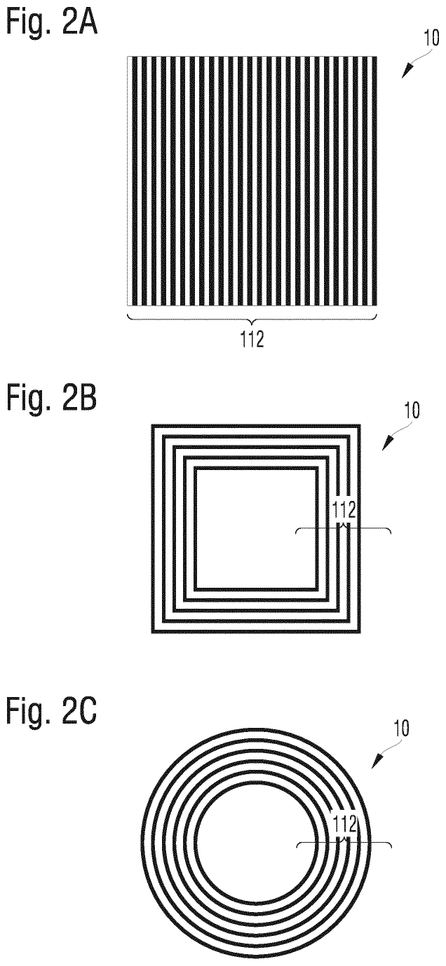

FIG. 2A shows a top view of a first main surface 11 of the optoelectronic semiconductor device according to embodiments. According to embodiments, as shown in FIG. 2A, the periodic structures or the lattice structure 112 may be formed to be linear. More precisely, for example, the first sub-layer 124 or the first main surface 109 of the semiconductor body 108 is patterned to form a plurality of parallel webs. The material of the conductive layer 123 or of the second sub-layer 125 is arranged between parallel webs. With such an arrangement of the lattice structure, the light may predominantly be emitted in two directions.

FIGS. 2B and 2C illustrate embodiments in which the lattice structures 112 each form a concentric structure around the center of the optoelectronic semiconductor device. For example, the optoelectronic semiconductor device 10 as shown in FIG. 2B may be embodied as a quadrangle. In this case, the lattice structure 112 is formed in the shape of rectangles which are arranged concentrically around the center of the optoelectronic semiconductor device.

In the embodiment shown in FIG. 2C, the optoelectronic semiconductor device may, for example, be formed to be circular. In this case, the lattice structure 112 may be formed in the shape of concentric circles. With an arrangement of the lattice structure 112 as shown in FIGS. 2B and 2C, for example, electromagnetic radiation may be emitted in all directions parallel to the surface.

Although specific embodiments have been illustrated and described herein, those skilled in the art will recognize that the specific embodiments shown and described may be replaced by a multiplicity of alternative and/or equivalent configurations without departing from the scope of the invention. The application is intended to cover any adaptations or variations of the specific embodiments discussed herein. Therefore, the invention is to be limited by the claims and their equivalents only.

### LIST OF REFERENCES

10 optoelectronic semiconductor device
11 first main surface of the optoelectronic semiconductor device
15 emitted electromagnetic radiation
100 substrate
105 first contact element
106 protruding semiconductor portion
107 second contact element
108 semiconductor body
109 first main surface of the semiconductor body
110 first semiconductor layer
112 lattice structure
115 active zone
120 second semiconductor layer
121 second main surface of the semiconductor body
122 portion of the conductive layer
123 conductive layer
124 first sub-layer
125 second sub-layer
127 space

1. An optoelectronic semiconductor device configured to emit electromagnetic radiation, wherein the device comprises:
a semiconductor body; and
a reflective lattice structure of layer portions arranged periodically in a horizontal direction directly adjacent to a first main surface of the semiconductor body, the first main surface being different from an exit surface of the electromagnetic radiation.

2. The optoelectronic semiconductor device according to claim 1, wherein a period of the reflective lattice structure is less than 500 nm.

3. The optoelectronic semiconductor device according to claim 1, wherein the lattice structure is patterned by a conductive layer in direct contact with the first main surface of the semiconductor body, the conductive layer being patterned periodically in the horizontal direction.

4. The optoelectronic semiconductor device according to claim 3, wherein the conductive layer comprises a first sub-layer of a first conductive material and a second sub-layer of a second conductive material, the first conductive material having a refractive index different from the refractive index of the second conductive material.

5. The optoelectronic semiconductor device according to claim 4, wherein the first conductive material is formed to be periodically patterned and the second conductive material is filled in spaces between portions of the first conductive material.

6. The optoelectronic semiconductor device according to claim 5, wherein the second conductive material has a smaller refractive index than the first conductive material.

7. The optoelectronic semiconductor device according to claim 5, wherein a difference of the refractive indices of the first conductive material and the second conductive material is greater than 1.0.

8. The optoelectronic semiconductor device according to claim 6, wherein the first conductive material is a transparent metal oxide and the second conductive material is silver.

9. The optoelectronic semiconductor device according to claim 1, wherein the first main surface of the semiconductor body is patterned periodically and the conductive layer is arranged between patterned semiconductor portions of the semiconductor body.

10. The optoelectronic semiconductor device according to claim 1, wherein the semiconductor body comprises a first semiconductor layer of a first conductivity type, a second semiconductor layer of a second conductivity type, and an active zone; wherein the active zone is arranged between the first semiconductor layer and the second semiconductor layer; and wherein the first semiconductor layer the active zone, and the second semiconductor layer form a layer stack.

11. The optoelectronic semiconductor device according to claim 10, wherein a first main surface of the first semiconductor layer is the first main surface of the semiconductor body.

12. The optoelectronic semiconductor device according to claim 10, wherein the first semiconductor layer is p-type.

13. The optoelectronic semiconductor device according to claim 1, wherein the lattice structure extends in the horizontal direction in a linear manner.

14. The optoelectronic semiconductor device according to claim 1, wherein the lattice structure extends in the horizontal direction in a circular and concentric manner.

15. The optoelectronic semiconductor device according to claim 1, wherein the lattice structure extends in the horizontal direction in a rectangular and concentric manner.

16. The optoelectronic semiconductor device according to any of claim 10, wherein a layer thickness of the first semiconductor layer is dimensioned such that an optical mode is formed between the first main surface of the semiconductor body and the active zone.

17. The optoelectronic semiconductor device according to claim 16, wherein the layer thickness of the first semiconductor layer corresponds to an integral multiple of half the wavelength of the electromagnetic radiation emitted.

18. An optoelectronic semiconductor device configured to emit electromagnetic radiation; wherein the device comprises:
a semiconductor body; and
a reflective lattice structure of layer portions arranged periodically in a horizontal direction directly adjacent to a first main surface of the semiconductor body, the first main surface being different from an exit surface of the electromagnetic radiation;
wherein the semiconductor body comprises a first semiconductor layer of a first conductivity type, a second semiconductor layer of a second conductivity type, and an active zone; wherein the active zone is arranged between the first semiconductor layer and the second semiconductor layer; and wherein the first semiconductor layer, the active zone, and the second semiconductor layer form a layer stack,
wherein the first main surface of the first semiconductor layer is the first main surface of the semiconductor body, and wherein the first semiconductor layer has a smaller layer thickness than the second semiconductor layer.

19. The optoelectronic semiconductor device according to claim 18, wherein a layer thickness of the first semiconductor layer is dimensioned such that an optical mode is formed between the first main surface of the semiconductor body and the active zone.

20. The optoelectronic semiconductor device according to claim 19, wherein the layer thickness of the first semiconductor layer corresponds to an integral multiple of half the wavelength of the electromagnetic radiation emitted.
